(19) United States
(12) Patent Application Publication
(10) Pub. No.: US 2025/0203817 A1
(43) Pub. Date: Jun. 19, 2025

(54) SPEAKER BOX

(71) Applicants: AAC ACOUSTIC TECHNOLOGIES (SHENZHEN) CO., LTD., Shenzhen (CN); AAC Microtech (Changzhou) Co., Ltd., Changzhou City, Jiangsu Province (CN)

(72) Inventors: Shuwen Wu, Shenzhen (CN); Zhenfan Ge, Shenzhen (CN)

(21) Appl. No.: 17/921,976

(22) PCT Filed: Apr. 20, 2022
(86) PCT No.: PCT/CN2022/087913

§ 371 Date: Mar. 12, 2025

(30) Foreign Application Priority Data
Apr. 7, 2022 (CN) 202210373711.8

(51) Int. Cl. H05K 7/20; H04R 1/02; H04R 1/06

(52) U.S. Cl. CPC H05K 7/2039; H04R 1/025; H04R 1/06; H05K 7/20263; H04R 2201/029

(57) ABSTRACT

The present application discloses a speaker box, including a casing with an accommodating cavity, and a sounding unit fixed in the accommodating cavity and dividing the accommodating cavity into a closed rear acoustic cavity and a front acoustic cavity communicated with an outside of the casing. The sounding unit is further provided with a heat exchange member, and a heat exchange cavity is formed in the heat exchange member. The heat exchange cavity is filled with a heat exchange medium, and part of the heat exchange element is exposed to the sounding unit. Compared with the prior art, in the present application, the sounding unit is provided with a heat exchange member. When the speaker box is in the working state, the sounding unit vibrates and generates heat, and the heat is conducted to the heat exchange medium in the heat exchange member through a wall of the heat exchange member. The heat exchange medium is in contact with the outside air of the sounding unit for heat exchange to release heat, thereby improving the heat dissipation efficiency of the speaker box.

### TECHNICAL FIELD

The present application relates to the technical field of electro-acoustic conversion, in particular to a speaker box.

### BACKGROUND

Speaker boxes are widely adopted in portable mobile electronic products, such as mobile phones, to convert audio signals into sound for playback. The speaker box has high loudness and good low-frequency sound effects.

A speaker box in the prior art includes a front cover, a rear cover covered on the front cover and enclosing an accommodating space with the front cover, and a sounding driver accommodated in the accommodating space, and the sounding driver divides the accommodating space into a front acoustic cavity and a rear acoustic cavity. However, the speaker box with poor heat dissipation in the related art limits acoustic performance.

### SUMMARY OF THE INVENTION

### Technical Problem

In view of the above-mentioned problem, the present application provides a speaker box, so as to solve the technical problem in the related art, making the speaker box have good heat dissipation.

### Solution to the Problem

### Technical Solution

In a first aspect, the present application provides a speaker box 10, comprising:
a casing with an accommodating cavity;
a sounding unit, fixed in the accommodating cavity and dividing the accommodating cavity into a closed rear acoustic cavity and a front acoustic cavity communicated with an outside of the casing;
wherein the sounding unit is further provided with a heat exchange member, and a heat exchange cavity is formed in the heat exchange member; the heat exchange cavity is filled with a heat exchange medium, and part of the heat exchange member is exposed to the sounding unit.

The speaker box described as above, wherein, preferably, the sounding unit comprises a sounding driver, and a supporting body for supporting the sounding driver on the heat exchange member; the heat exchange member is embedded in the the supporting body and is arranged in a circumferential side of the sounding driver, and part of the heat exchange member is exposed to the supporting body.

The speaker box described as above, wherein, preferably, the heat exchange member is made of metal.

The speaker box described as above, wherein, preferably, the heat exchange member and the supporting body are integrally formed by injection molding.

The speaker box described as above, wherein, preferably, a first end of the supporting body is accommodated in the accommodating cavity, and the casing is provided with a first groove connected to the accommodating cavity; a second end of the supporting body is extended to the outside of the casing through the first groove; the supporting body is provided with a second groove and a third groove; the second groove is arranged through the first end of the supporting body; one end of the third groove forms an opening on the second end of the supporting body, and the other end of the third groove is extended to communicate with the second groove;
the sounding driver is supported on the second groove; the sounding driver, the accommodating cavity, the second groove and the third groove together form a front acoustic cavity, and the sounding driver, the supporting body and the accommodating cavity together form a closed rear acoustic cavity.

The speaker box described as above, wherein, preferably, the second groove is a stepped groove.

The speaker box described as above, wherein, preferably, the casing comprises a front cover and a rear cover that are respectively covered on opposite sides of the sounding driver along a vibration direction of the sounding driver; the rear cover comprises a main plate arranged opposite to the front cover and a side plate bent and extended along a direction of the front cover from an outer peripheral edge of the main plate and is fixedly connected to the front cover, and the side plate is abutted against the front cover for sealing and fixing.

The speaker box described as above, wherein, preferably, the side plate is provided with a fourth groove connected to the rear acoustic cavity; the casing is provided with a sealing cover attached to the casing, and the sealing cover is completely covered on the fourth groove.

The speaker box described as above, wherein, preferably, the speaker box further comprises a conductive terminal configured to electrically connect the sounding driver to an outside world, and the conductive terminal is arranged through the casing and is partially exposed to the casing.

The speaker box described as above, wherein, preferably, the side plate is provided with a fifth groove formed by an end of the side plate close to the front cover recessed toward the main plate; the conductive terminals is extended outside the casing through the fifth groove, and the front cover is covered on the conductive terminal and the side plate for sealing and fixing.

### Beneficial Effect of the Invention

### Beneficial Effect

Compared with the related art, in the present application, a heat exchange member is provided in the sounding unit. When the speaker box is in a working state, the sounding unit vibrates and generates heat, and the heat is conducted to the heat exchange medium inside the heat exchange member through a wall of the heat exchange member, and then the heat exchange medium is in contact with the air outside the sounding unit for heat exchange to release the heat, thereby improving the heat dissipation efficiency of the speaker box.

Described above is only an overview of the technical solutions of the present application, in order to understand the technical means of the present application more clearly, it may be implemented according to the content of the description. Besides, in order to make the above and other objects, features and advantages of the present application are more obvious and are easy to understand, the following specific embodiments of the present application are provided.

### BRIEF DESCRIPTION OF THE DRAWINGS

### Description of the Drawings

Various other advantages and benefits will become apparent to those of ordinary skill in the art upon reading the following detailed description of the preferred embodiments. The drawings are used for the purpose of illustrating preferred embodiments only and are not to limit the present application. Besides, the same components are denoted by the same reference numbers throughout the accompanying drawings. In the accompanying drawings:

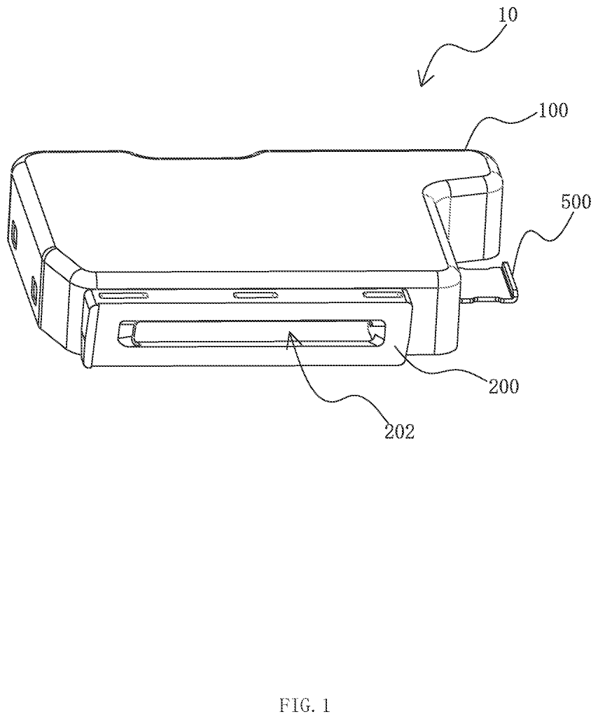

FIG. 1 is a perspective view of an overall structure of a speaker box according to an embodiment of the present application.

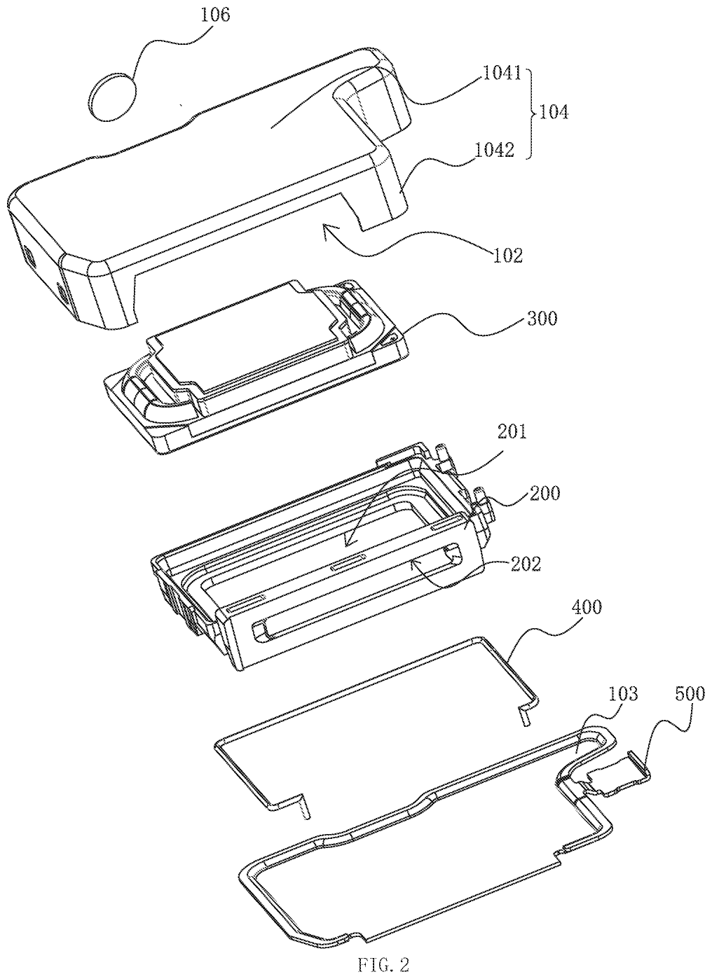

FIG. 2 is an exploded view of the overall structure of the speaker box according to an embodiment of the present application.

FIG. 3 is a front view of the overall structure of the speaker box according to an embodiment of the present application.

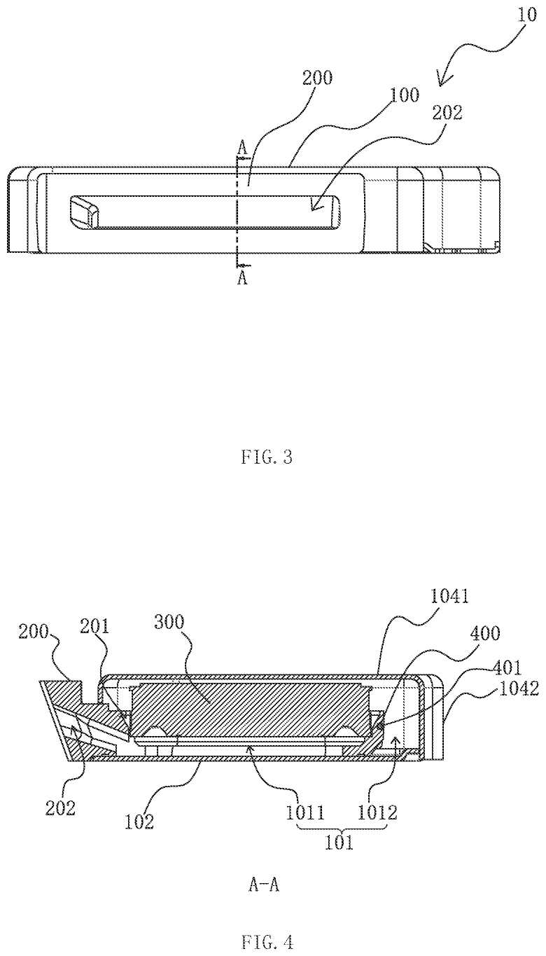

FIG. 4 is a sectional view of the overall structure of the speaker box in FIG. 3 along a direction of A-A.

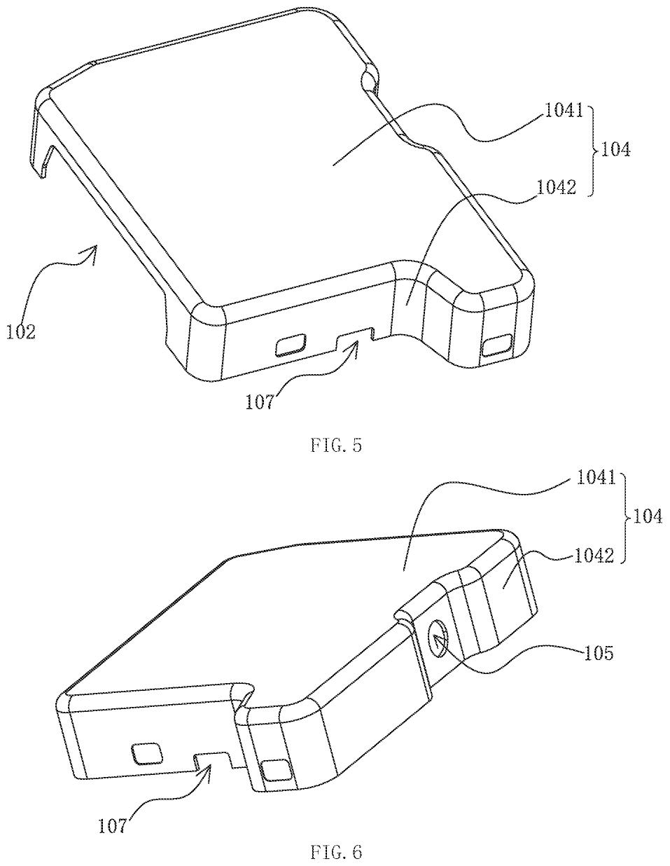

FIG. 5 is a perspective view of a rear cover from one angle according to an embodiment of the present application.

FIG. 6 is a perspective view of the rear cover from another angle according to an embodiment of the present application.

In the accompanying drawings, the structures are not necessarily drawn to practical scale.

The reference numbers in the specific embodiments are as follows:
10—Speaker box;
100—Casing; 101—Accommodating cavity; 1011—Front acoustic cavity; 1012—Rear Acoustic cavity; 102—First groove; 103—Front cover; 104—Rear cover; 1041—Main plate; 1042—Side plate; 105—Fourth groove; 106—Sealing cover, 107—Fifth groove;
200—Supporting plate; 201—Second groove; 202—Third groove;
300—Sounding driver;
400—Heat exchange member; 401—Heat exchange cavity;
500—Conductive terminal;

### BEST EMBODIMENTS FOR PRACTICING THE INVENTION

### Best Embodiments for the Invention

The embodiments described below with reference to the accompanying drawings are exemplary and are only used to explain the present application, but not to be construed as a limitation of the present application.

The speaker box in the related art has the technical defect of poor heat dissipation. it is found from researches that when the sounding unit in the speaker box is in a working state, the generated heat is transmitted to the rear acoustic cavity and the front acoustic cavity through the air for heat dissipation. On the one hand, a bracket for supporting the sounding body is a plastic structure, which has poor thermal conductivity and low heat dissipation efficiency. On the other hand, the hot air in the rear acoustic cavity is trapped in the rear acoustic cavity, and can only contact the outside air through a leak hole, resulting in poor heat dissipation and limited acoustic performance.

In order to improve the heat dissipation performance of the speaker box 10, as shown in FIGS. 1-6, the present application provides a speaker box 10, including a casing 100 and a sounding unit.

The interior of the casing 100 has an accommodating cavity 101, and the sounding unit is fixed in the accommodating cavity 101. The sounding unit has a diaphragm for vibrating and sounding. The sounding unit divides the accommodating cavity 101 into a closed rear acoustic cavity 1012 and a front acoustic cavity 1011 communicated with an outside of the casing 100, and the diaphragm is accommodated in the front acoustic cavity 1011.

There is further a heat exchange member 400 in the sounding unit, and the heat exchange cavity 401 is formed in the heat exchange member 400. The heat exchange cavity 401 is filled with a heat exchange medium, and part of the heat exchange member 400 is exposed to the sounding unit, so that the heat exchange member 400 can be contacted with the sounding unit and the outside air. Therefore, the heat exchange member 400 can conduct and exchange heat between the sounding unit and the outside air. The heat exchange medium is preferably cooling liquid. When the speaker box 10 is in a working state, the sounding unit vibrates to generate heat, and the heat is conducted to the heat exchange medium in the heat exchange cavity 401 through a wall of the heat exchange element 400, and then the heat exchange medium contacts the air outside the sounding unit through the wall of the heat exchange member 400 exposed to the air to conduct heat exchange and release heat, thereby reducing the temperature of the sounding unit and improving the heat dissipation efficiency of the speaker box 10.

Further, as shown in FIG. 2 and FIG. 4, the sounding unit includes a sounding driver 300 and a supporting body 200 supporting the sounding driver 300 on the heat exchange member 400. The heat exchange member 400 is embedded in the supporting body 200, and arranged in a circumferential side of the sounding driver 300. Part of the heat exchange member 400 is exposed to the supporting body 200.

In some embodiments, the heat exchange member 400 is a hollow tube body structure, and the tube body structure is bent into a substantially annular or square shape as a whole. A main body of the heat exchange member 400 is embedded in the supporting body 200, and a main part of the heat exchange member 400 is wrapped in the supporting body 200, so that the heat generated by the sounding driver 300 is dissipated and absorbed by the supporting body 200, and then transmitted to the the heat exchange member 400. Main parts of the heat exchange member 400 can absorb heat uniformly, so that the heat exchange effect with the air can be improved. A head end and a tail end of the heat exchange member 400 are exposed to the outside of the supporting body 200 to exchange heat with the air. An injection port is formed at at least one end of the head end and the tail end, so that the cooling liquid is injected through the injection port. The injection port is sealed or welded with glue after injection, thereby completing the filling of heat exchange medium.

Further, the heat exchange member 400 is made of metal material, and the heat exchange member 400 made of metal material has good thermal conductivity. When the diaphragm in the sounding driver 300 is in the working state, the heat generated by the vibration is more rapidly and efficiently conducted on the heat exchange member 400, thereby improving the overall heat dissipation performance of the speaker box 10.

Further, in order to improve the assembly efficiency of the heat exchange member 400 and the supporting body 200 and facilitate the molding process, in some embodiments, the heat exchange member 400 and the supporting body 200 are integrally formed by injection molding. The molding in this way is relatively simple and has high production efficiency. Specifically, a preparation process of the heat exchange member 400 and the supporting body 200 is as follows.
Step 1: the heat exchange member 400 in the shape of a metal tube body is formed.
Step 2: the heat exchange member 400 is positioned in a mold for injection molding; the heat exchange member 400 is molded into the supporting body 200, and the two ends of the heat exchange member 400 is exposed to the outside of the supporting body 200, so as to form an injection port.
Step 3: the cooling liquid is injected through the injection port, and then the injection port is sealed by glue or welding after injection, so as to complete the assembly processing.

Further, as shown in FIG. 4, a first end of the supporting body 200 is fixedly accommodated in the accommodating cavity 101. The casing 100 is provided with a first groove 102 communicated with the accommodating cavity 101. A second end of the supporting body 200 is extended to outside the casing 100 through the first groove 102. Preferably, the supporting body 200 is made of plastic material and has a ring structure. The supporting body 200 is provided with a second groove 201 and a third groove 202. The second groove 201 is arranged through the first end of the supporting body 200 to form an annular structure. One end of the third groove 202 forms an opening on the second end of the supporting body 200, and the opening is located outside the casing 100. The other end of the third groove 202 is extended to communicate with the second groove 201. The above structure forms a side sounding structure of the speaker box 10, so that a shape of the speaker box 10 is matched with a shape of a whole machine, which is beneficial to a flexible assembly of the speaker box 10 in the whole machine.

The sounding driver 300 is supported on the second groove 201. A side of the sounding driver 300 with the diaphragm is arranged toward the second groove 201, and is spaced from an inner wall of the accommodating cavity 101. A groove wall of the second groove 201 is arranged on a peripheral side of the sounding driver 300, so that the sounding driver 300 and the second groove 201 are sealed and fixed. The sounding driver 300, the accommodating cavity 101, the second groove 201 and the third groove 202 together form the front acoustic cavity 1011. The sounding driver 300, the supporting body 200 and the accommodating cavity 101 together form the closed rear acoustic cavity 1012.

Further, as shown in FIG. 4, the second groove 201 is a stepped groove with a groove portion that is gradually bent and contracted. The sounding driver 300 is fixed in the stepped groove, and the sounding driver 300 and the supporting body 200 can be overlapped in a thickness direction of the supporting body 200, thereby reducing a space occupied by the sounding driver 300, which is beneficial to the miniaturization of the speaker box 10.

In some embodiments, as shown in FIG. 2 and FIG. 4, the casing 100 is in a split structure, so as to facilitate molding, processing and assembly. Specifically, the casing 100 includes a front cover 103 and a rear cover 104 that are respectively covered on opposite sides of the sounding driver 300 along a vibration direction of the diaphragm of the sounding body 300. The front cover 103 is a plate structure. The rear cover 104 includes a main plate 1041 opposite to the front cover 103 and a side plate 1042 bent and extended toward the front cover 103 from a periphery of the main plate 1041 and fixedly connected to the front cover 103. The side plate 1042 is abutted against the front cover 103 for sealing and fixing.

Further, the casing 100 and the cover plate are both made of metal. On the premise of ensuring the structural strength of the casing 100, the casing 100 made of metal can be designed to be thinner than the all-plastic casing 100. Moreover, since the front cover 103 and the rear cover 104 made of metal materials can be fixed by metal welding, there is no need to reserve more space for ultrasonic welding. While assembling the sounding body 300 effectively, the metal casing greatly increases the volume of the cavity of the casing 100, and effectively increases a volume of the rear acoustic cavity 1012 enclosed by the sounding body 300 and the casing 100, thereby improving the acoustic performance of the speaker box 10, especially the low-frequency acoustic performance.

Further, referring to FIG. 5 and FIG. 6, the side plate 1042 is provided with a fourth groove 105 communicated with the rear acoustic cavity 1012. The casing 100 is provided with a sealing cover 106 attached to the casing 100. The sealing cover 106 is completely covered on the fourth groove 105. The fourth groove 105 is configured to improve the air pressure balance between the rear acoustic cavity 1012 and the outside world. The sealing cover 106 can seal the fourth groove 105 after the sound-absorbing material is filled into the rear acoustic cavity 1012 through the fourth groove 105, so that the assembly of the speaker box 10 is simpler and more reliable.

Further, as shown in FIG. 1 and FIG. 4, the speaker box 10 further includes a conductive terminal 500 for electrically connecting the sounding driver 300 to the outside world. The conductive terminal 500 is arranged through the casing 100 and is partially exposed to the casing 100.

In some embodiments, as shown in FIG. 1, FIG. 5 and FIG. 6, the side plate 1042 is provided with a fifth groove 107 formed by one end of the side plate 1042 close to the front cover 103 recessed toward the main plate 1041. The conductive terminal 500 is extended outside of the casing 100 through the fifth groove 107, and the front cover 103 is covered on the conductive terminal 500 and the side plate 1042 for sealing and fixing. This structure is convenient for assembly and improves assembly efficiency.

The structures, features and effects of the present application have been described in detail above according to the embodiments shown in the drawings. Described above are only preferred embodiments of the present application, but the scope of implementation of the present application is not limited by the drawings. Any changes made in accordance with the concept of the present application, or modifications to equivalent embodiments with equivalent changes without exceeding the spirit covered by the description and drawings shall fall within the protection scope of the present application.

What is claimed is:

1. A speaker box, comprising:
a casing with an accommodating cavity;
a sounding unit, fixed in the accommodating cavity and dividing the accommodating cavity into a closed rear acoustic cavity and a front acoustic cavity communicated with an outside of the casing;
wherein the sounding unit is further provided with a heat exchange member, and a heat exchange cavity is formed in the heat exchange member; the heat exchange cavity is filled with a heat exchange medium, and part of the heat exchange member is exposed to the sounding unit.

2. The speaker box of claim 1, wherein the sounding unit comprises a sounding driver, and a supporting body for supporting the sounding driver on the heat exchange member; the heat exchange member is embedded in the the supporting body and is arranged in a circumferential side of the sounding driver, and part of the heat exchange member is exposed to the supporting body.

3. The speaker box of claim 2, wherein the heat exchange member is made of metal.

4. The speaker box of claim 3, wherein the heat exchange member and the supporting body are integrally formed by injection molding.

5. The speaker box of claim 2, wherein a first end of the supporting body is accommodated in the accommodating cavity, and the casing is provided with a first groove connected to the accommodating cavity; a second end of the supporting body is extended to the outside of the casing through the first groove; the supporting body is provided with a second groove and a third groove; the second groove is arranged through the first end of the supporting body; one end of the third groove forms an opening on the second end of the supporting body, and the other end of the third groove is extended to communicate with the second groove;
the sounding driver is supported on the second groove; the sounding driver, the accommodating cavity, the second groove and the third groove together form a front acoustic cavity, and the sounding driver, the supporting body and the accommodating cavity together form a closed rear acoustic cavity.

6. The speaker box of claim 5, wherein the second groove is a stepped groove.

7. The speaker box of claim 2, wherein the casing comprises a front cover and a rear cover that are respectively covered on opposite sides of the sounding driver along a vibration direction of the sounding driver; the rear cover comprises a main plate arranged opposite to the front cover and a side plate bent and extended along a direction of the front cover from an outer peripheral edge of the main plate and is fixedly connected to the front cover, and the side plate is abutted against the front cover for sealing and fixing.

8. The speaker box of claim 7, wherein the side plate is provided with a fourth groove connected to the rear acoustic cavity; the casing is provided with a sealing cover attached to the casing, and the sealing cover is completely covered on the fourth groove.

9. The speaker box of claim 7, further comprising a conductive terminal configured to electrically connect the sounding driver to an outside world, and the conductive terminal is arranged through the casing and is partially exposed to the casing.

10. The speaker box of claim 9, wherein the side plate is provided with a fifth groove formed by an end of the side plate close to the front cover recessed toward the main plate; the conductive terminals is extended outside the casing through the fifth groove, and the front cover is covered on the conductive terminal and the side plate for sealing and fixing.
